(19) United States
(12) Patent Application Publication
(10) Pub. No.: US 2016/0099162 A1
(43) Pub. Date: Apr. 7, 2016

(54) SINGLE RING DESIGN FOR HIGH YIELD, SUBSTRATE EXTREME EDGE DEFECT REDUCTION IN ICP PLASMA PROCESSING CHAMBER

(71) Applicant: APPLIED MATERIALS, INC., Santa Clara, CA (US)

(72) Inventors: Siu Tang NG, Cupertino, CA (US); Changhun LEE, San Jose, CA (US); Huutri DAO, San Jose, CA (US); Adam LANE, Campbell, CA (US); Michael D. WILLWERTH, Campbell, CA (US)

(21) Appl. No.: 14/765,872

(22) PCT Filed: Apr. 30, 2014
(86) PCT No.: PCT/US2014/036213

§ 371 Date: Aug. 5, 2015

Related U.S. Application Data
(60) Provisional application No. 61/839,823, filed on Jun. 26, 2013.

(51) Int. Cl. H01L 21/683; H01J 37/32

(52) U.S. Cl. CPC H01L 21/683; H01J 37/32642

(57) ABSTRACT

Embodiments of the invention provide a single ring comprising a circular ring-shaped body with an inner surface, closest in proximity to a centerline of the body, and an outer surface opposite the inner surface. The body has a bottom surface with a slot formed therein and a top surface with an outer end, adjacent to the outer surface, and an inner end adjacent to a slope extending, towards the centerline, down to a step on the inner surface. The body has a lip, disposed on the inner surface extending out from a vertical face below the step toward the centerline of the body, and is configured to support a substrate thereon. The body is sized such that a gap of less than about 2 mm is formed on the lip between the substrate and the vertical face of the step.

### BACKGROUND OF THE DISCLOSURE

1. Field

The embodiments herein generally relate to a single ring process kit for use in a plasma processing chamber.

2. Description of the Background Art

Various semiconductor fabrication processes, such as plasma-assisted etching, physical vapor deposition, and chemical vapor deposition, among others, are performed in plasma processing chambers in which a semiconductor work pieces engaged with a dielectric collar (also known as a cover ring) during processing. For example in a plasma processing chamber configured for etching a work piece such as a semiconductor substrate, the substrate is mounted on substrate support pedestal within the processing chamber. The substrate support pedestal includes a metal electrode to which an RF bias may be applied to sustain a plasma formed from a mixture of process gases provided to the processing chamber. The pressure within the processing chamber is maintained by a pump which also removes etch by-products from the chamber. An RF power supply is coupled to the electrode inside the substrate support pedestal so as to produce on the electrode a negative bias voltage relative to the plasma. The bias voltage attracts ions to bombard the work piece so as to promote the desired fabrication process. Because the electrode is negatively biased, the substrate support pedestal often is called the cathode.

The cathode is typically surrounded by covers and liners to protect the cathode from damage due to the ion bombardment. For example, a liner may be utilized to surround the sidewalls of the cathode, while a cover ring is utilized to cover the upper surface of the cathode. Since the substrate typically is positioned inside the cover ring while supported on the substrate, ample tolerances and gaps are required between the substrate and cover ring to allow the substrate to be placed on, and removed from, the substrate support pedestal using conventional robotic mechanisms. These gaps are generally maintained in excess of 3.0 um to accommodate the above mentioned substrate motion and thereby allow interface with the robotic mechanisms without substrate damage due to misalignment.

However, the gap between the substrate and the cover ring also allows the migration of free radicals from the plasma to pass below the edge of the substrate. It has been found that particularly during aluminum etching, the gap between the cover ring and substrate allows a significant amount of free radicals to reach the back side of the substrate. The free radicals interact with the edge and backside of the substrate to create defects, such as bevel peeling and particle generation.

As circuit densities increase for next generation devices, critical dimensions, such as the width or pitch of interconnects, vias, trenches, contacts, devices, gates and other features, as well as the dielectric materials disposed therebetween, are correspondingly decreasing. Additionally, further scaling of devices increases the impact from particles introduced into the manufacturing process, such as those through defects such as bevel peeling. In smaller devices, the size and number of particles have a greater effect on device performance and can undesirably change the electrical properties of the device, including bridging between interconnect features. Therefore, the tolerance to the amount and size of particles and associated manufacturing defects has decreased, making gaps between the cover ring and substrate which were once was acceptable for larger critical dimensions no longer good enough for smaller, next generation devices.

While conventional cover rings have been found to improve older semiconductor fabrication processes, further improvements for preventing radical migration for the purpose of preventing edge defects are needed to enable commercially viable device yields in the manufacture of next generation devices.

### SUMMARY

Embodiments of the invention provide a single ring comprising a circular ring-shaped body with an inner surface, closest in proximity to a centerline of the body, and an outer surface opposite the inner surface. The body has a bottom surface with a slot formed therein and a top surface with an outer end, adjacent to the outer surface, and an inner end adjacent to a slope extending, towards the centerline, down to a step on the inner surface. The body has a lip, disposed on the inner surface extending out from a vertical face below the step toward the centerline of the body, and is configured to support a substrate thereon. The body is sized such that a gap of less than about 2 mm is formed on the lip between the substrate and the vertical face of the step.

### BRIEF DESCRIPTION OF THE DRAWINGS

So that the manner in which the above recited features of the embodiments herein are attained and can be understood in detail, a more particular description of the invention, briefly summarized above, may be had by reference to the embodiments thereof which are illustrated in the appended drawings.

FIG. 1 depicts an ICP plasma processing chamber having a cover ring.

FIG. 2 depicts a top view of the cover ring depicted in FIG. 1.

FIG. 3 depicts a cross sectional view for the cover ring depicted in FIG. 1.

FIG. 4 illustrates edge defects on an extreme edge and backside of a substrate after etching in a ICP plasma processing chamber utilizing a conventional wide gap cover ring.

FIG. 5 illustrates the extreme edge and backside after etching in a ICP plasma processing chamber utilizing the cover ring depicted in FIG. 1.

To facilitate understanding of the embodiments, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

Embodiments of the invention provide a cover ring that enables extreme edge and backside particle defect reduction over conventional substrate processing which may result in bevel polymer peeling after a plasma etch process. Beneficially, the cover ring enables etching of aluminum (Al) bond pad thicknesses beyond the 3.5 um technology.

The new cover ring design provides a narrow gap between the extreme edge of the substrate and the ring. During the etching of an Al bond pad, the narrow gap prevents polymers and radicals (i.e. radical migration) from attacking the extreme edge and the backside of the substrate. The substrate initially undergoes a deposition of a metallic film coating. Examples of some metallic film coatings may be (TiN/Ti/AL/Ti/TiN). The metallic film coating has a photoresist mask produced using a lithographic operation. The metallic film is then etched in a processing chamber. The cover ring used in the processing chamber has a narrow gap defined between the substrate and cover ring, for example from less than about 2 mm down to at least about 0.9 mm, so as to substantially reduce the flow of plasma free radicals around the extreme edge of the substrate.

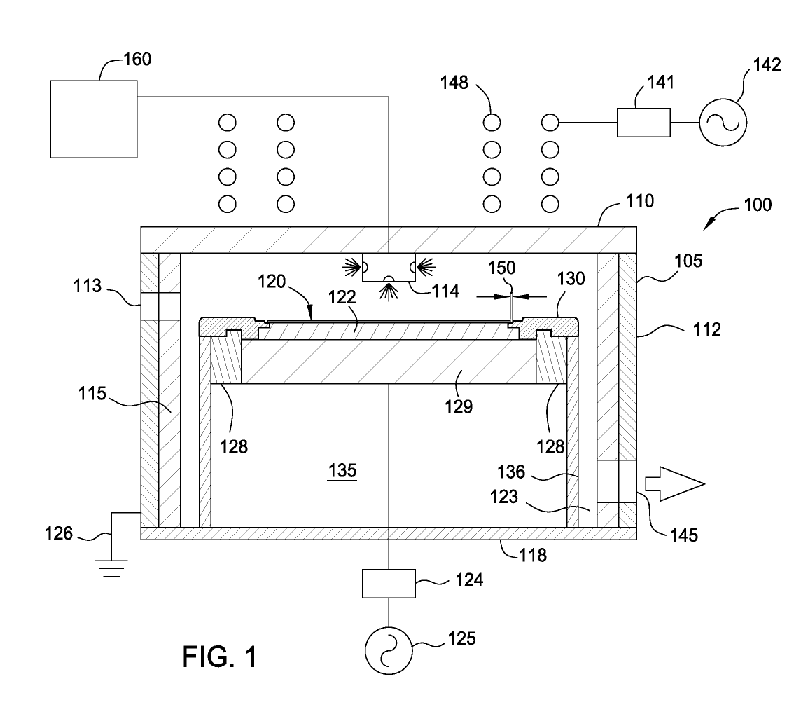

FIG. 1 illustrates an exemplary processing chamber 100 having a cover ring 130. The exemplary processing chamber 100 is configured as an etch processing chamber and is suitable for removing one or more material layers from a substrate. One example of the process chamber that may be adapted to benefit from the invention is an AdvantEdge Mesa Etch processing chamber, available from Applied Materials, Inc., located in Santa Clara, Calif. It is contemplated that other process chambers, including those from other manufactures, may be adapted to practice embodiments of the invention.

The process chamber 100 includes a chamber body 105 having a processing volume defined therein. The chamber body 105 has sidewalls 112 and a bottom 118 and a ground shield assembly 126 coupled thereto. The sidewalls 112 have a liner 115 to protect the sidewalls 112 and extend the time between maintenance cycles of the process chamber 100. The dimensions of the chamber body 105 and related components of the process chamber 100 are not limited and generally are proportionally larger than the size of the substrate 120 to be processed therein. Examples of substrate sizes include, among others, substrates 120 with a 150 mm diameter, 200 mm diameter, a 300 mm diameter and 450 mm diameters, among others.

A chamber lid assembly 110 is mounted on the top of the chamber body 105. The chamber body 105 may be fabricated from aluminum or other suitable materials. A substrate access port 113 is formed through the sidewall 112 of the chamber body 105, facilitating the transfer of the substrate 120 into and out of the process chamber 100. The access port 113 may be coupled to a transfer chamber and/or other chambers of a substrate processing system (both not shown).

A pumping port 145 is formed through the sidewall 112 of the chamber body 105 and connected to the chamber volume through the exhaust manifold 123. A pumping device (not shown) is coupled to the processing volume to evacuate and control the pressure therein. The pumping device may include one or more pumps and throttle valves. The pumping device and chamber cooling design enables high base vacuum (about 1×E⁻⁸ Torr or less) and low rate-of-rise (about 1,000 mTorr/min) at temperatures suited to thermal budget needs, e.g., about −25 degrees Celsius to about +500 degrees Celsius.

A gas source 160 is coupled to the chamber body 105 to supply process gases into the processing volume. In one or more embodiments, process gases may include inert gases, non-reactive gases, and reactive gases if necessary. Examples of process gases that may be provided by the gas source 160 include, but not limited to, carbon tetrafluoride (CF₄), hydrogen bromide (HBr), argon gas (Ar), chlorine (Cl₂), oxygen gas (O₂), among others. Additionally, combinations of the gases may be supplied to the chamber body 105 from the gas source 160. For instance, a mixture of HBr and O₂ may be supplied into the processing volume to etch an aluminum (Al) containing substrate.

The lid assembly 110 generally includes a nozzle 114. The nozzle 114 has one or more ports for introducing process gas from the gas supply 160 into the processing volume. After the process gas is introduced into the chamber 100, the gas is energized to form plasma. An antenna 148, such as one or more inductor coils, may be provided adjacent the processing chamber 100. An antenna power supply 142 may power the antenna 148 through a match circuit 141 to inductively couple energy, such as RF energy, to the process gas to maintain a plasma formed from the process gas in the processing volume within the chamber 100. Alternatively, or in addition to the antenna power supply 142, process electrodes comprising a cathode below the substrate 120 and an anode above the substrate 120 may be used to capacitively couple RF power to the process gases to maintain the plasma within the processing volume. The operation of the power supply 142 may be controlled by a controller that also controls the operation of other components in the chamber 100.

A substrate support pedestal 135 may include an electro-static chuck 122 for holding the substrate 120 during processing. The electro-static chuck (ESC) 122 uses the electro-static attraction to hold the substrate 120 to the substrate support pedestal 135 for an etching process. The ESC 122 is powered by an RF power supply 125 integrated with a match circuit 124. The ESC 122 comprises an electrode embedded within a dielectric body. The RF power supply 125 may provide a RF chucking voltage of about 200 volts to about 2000 volts to the electrode. The RF power supply 125 may also include a system controller for controlling the operation of the electrode by directing a DC current to the electrode for chucking and de-chucking the substrate 120. The ESC 122 has an isolator 128 for the purpose of making the sidewall of the ESC 122 less attractive to the plasma. Additionally, the substrate support pedestal 135 has a cathode liner 136 to protect the sidewalls of the substrate support pedestal 135 from the plasma gasses and to extend the time between maintenance of the plasma processing chamber 100. The cathode liner 136 and the liner 115 may be formed from a ceramic material. For example, both the cathode liner 136 and liner 115 may be formed from Yttria.

The ESC 122 is configured to perform in the temperature range required by the thermal budget of the device being fabricated on the substrate 120. For example, the ESC may be configured to maintain the substrate 120 at a temperature of about minus about 25 degrees Celsius to about 100 degrees Celsius for certain embodiments, at temperature of about 100 degrees Celsius to about 200 degrees Celsius temperature range for other embodiments, and at about 200 degrees Celsius to about 500 degrees Celsius for yet still other embodiments. A cooling base 129 is provided to protect the substrate support pedestal 135 and assists in controlling the temperature of the substrate 120.

The cover ring 130 is disposed on the ESC 122 and along the periphery of the substrate support pedestal 135. A gap 150 is formed between the cover ring 130 and the substrate 120 therein. The cover ring 130 is configured to confine etching gases, radicals, to a desired portion of the exposed top surface of the substrate 120, while shielding the top surface of the substrate support pedestal 135 from the plasma environment inside the processing chamber 100. As the substrate support pedestal 135 is raised to the upper position for processing, an outer edge of the substrate 120 disposed on the substrate support pedestal 135 is surrounded on its periphery by, and in close proximity to, the cover ring 130. Lift pins (not shown) are selectively moved through the substrate support pedestal 135 to lift the substrate 120 above the substrate support pedestal 135 to facilitate access to the substrate 120 by a transfer robot or other suitable transfer mechanism.

A controller may be coupled to the process chamber 100. The controller may include a central processing unit (CPU), a memory, and support circuits. The controller is utilized to control the process sequence, regulating the gas flows from the gas source 160 into the process chamber 100 and other process parameters. The CPU may be of any form of a general purpose computer processor that can be used in an industrial setting. The software routines can be stored in the memory, such as random access memory, read only memory, floppy or hard disk drive, or other form of digital storage. The support circuits are conventionally coupled to the CPU and may comprise cache, clock circuits, input/output subsystems, power supplies, and the like. The software routines, when executed by the CPU, transform the CPU into a specific purpose computer (controller) that controls the process chamber 100 such that the processes are performed in accordance with the present invention. The software routines may also be stored and/or executed by a second controller (not shown) that is located remotely from the process chamber 100.

During processing, gas is introduced into the process chamber 100 to form a plasma and etch the surface of the substrate 120. The substrate support pedestal 135 is biased by the power source 125 and an RF antenna 148 is biased by the power supply 142 to maintain the plasma formed from the process gases supplied by the gas source 160. Ions from the plasma are attracted to the cathode in the substrate support pedestal 135 and etch the substrate 120. The cover ring 130 prevents the free radicals in the plasma from attacking the extreme edge or underside of the substrate 120, while preventing plasma damage to the top surface of the substrate support pedestal 135.

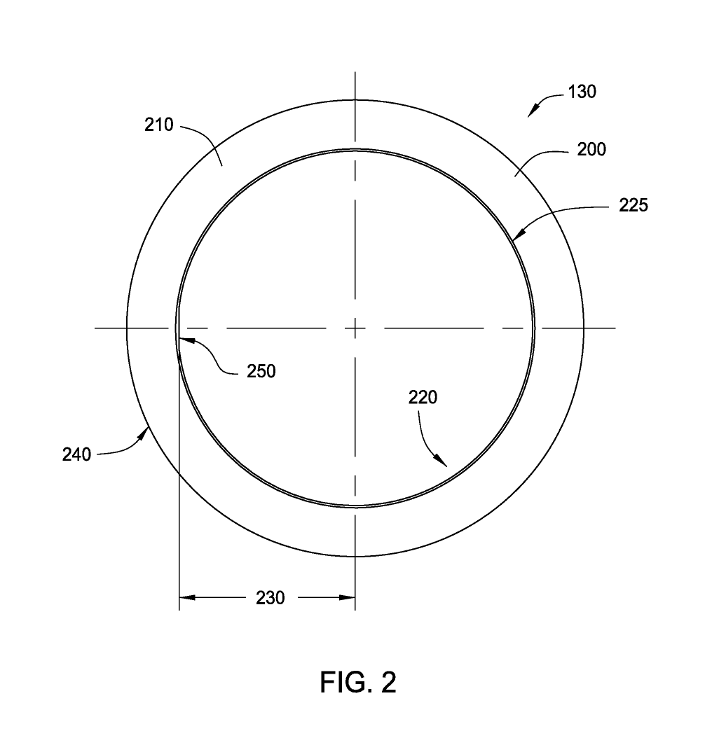

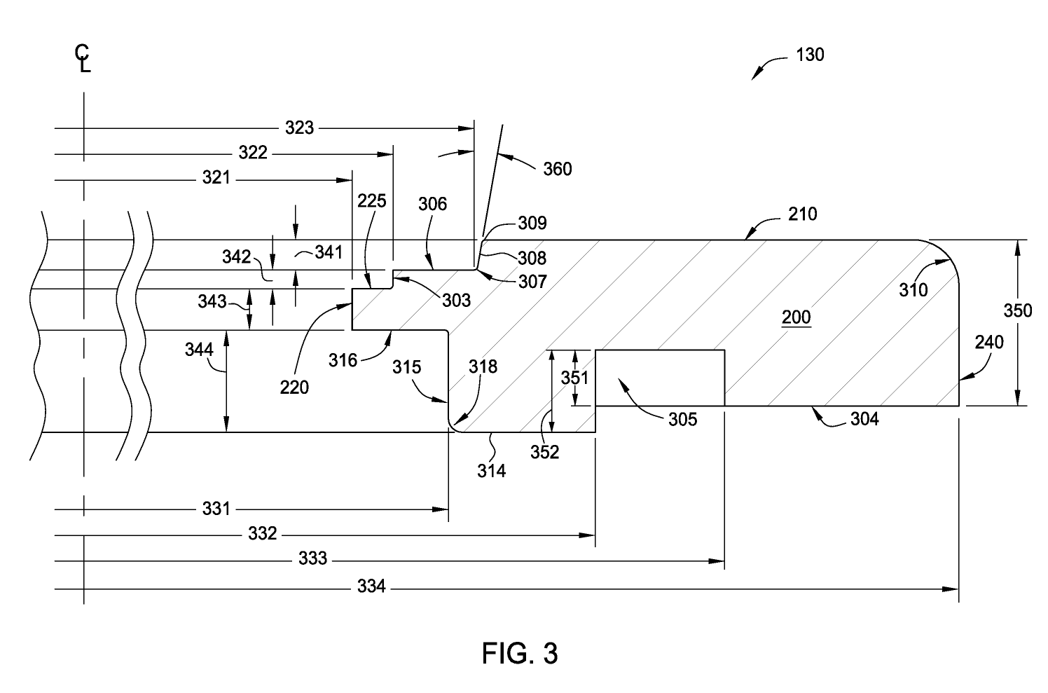

The configuration of the cover ring 130 in plasma processing chamber 100 is specific to the diameter of the substrate 120. For instance, a cover ring 130 configured for use with a 200 mm diameter substrate would be sized differently than cover ring 130 configured for use with a 300 mm or 450 mm diameter substrate. The gap 150 defined between substrate 120 and the ring 130 controls the flow of free radicals and therefore influences the amount of edge defects which may be formed on the substrate 120. To better understand the causal relationship between edge defects on the substrate 120 and the cover ring 130, the cover ring 130 will be described below in greater detail with reference to FIGS. 2 and 3.

FIG. 2 depicts a top view of the cover ring 130. The cover ring 130 has a single ring-shaped body 200 that includes a top 210 surface having, an inside edge 220 and an outside edge 240. The outside edge 240 of the single ring-shaped body 200 is configured to fit a substrate pedestal in a plasma processing chamber. The inside edge 220, of the single ring-shaped body 200, forms a lip 225 on which the substrate rests upon. Additionally, the single ring body 200 has a flat 250 which corresponds to a flat formed in the perimeter of substrate. The flat 250 is a distance 230 measured perpendicular from the flat 250 to the center of the single ring body 200. The distance 230 determines the size of the single ring body 200, and is sized according the diameter of the substrate processed in the processing chamber. In one or more embodiments, the single ring body 200 is comprised of an yttrium (Y) containing material, for example, bulk yttrium oxide (Y₂O₃). The material of the cover ring body 200 provides enhanced resistance to corrosion thereby improving the service lifetime of the chamber component and thus reducing maintenance cost.

The single ring body 200 may be configured to fit 200 mm, 300 mm, 450 mm or any conceivably sized substrate. A single ring body 200, configured for a 300 mm diameter substrate, has a radial distance 230 of 5.825+0.005/−0.000 inches. The inside edge 220 is described with a diameter of 11.736+0.005/−0.000 inches (295.91 mm to 296.16 mm). The outside edge 240 is described with a diameter of 15.12 inches (384.05 mm). The 300 mm diameter substrate rest on top of the lip formed by the inside edge 220. The lip 225 has a second vertical face opposite the vertical face of the inside edge 220. The second vertical face forms a cylindrical wall sized to accept the 300 mm diameter substrate therein.

A more detail look for ring body 200 can be found in FIG. 3. FIG. 3 depicts a cross sectional view for the single ring body 200 designed for an ICP plasma processing chamber. The single ring body 200 generally includes a body 200 that may be fabricated from a ceramic material such as yttria, or other acceptable material.

The body 200 includes the outside edge 240 and the inside edge 220. In the following example, the single ring body 200 is sized for a 300 mm diameter substrate. The outside edge 240 and inside edge 220 are substantially vertical cylindrical walls that are concentric in orientation, while the outer bottom 304 and the top 210 are substantially horizontal.

The inside edge 220 of ring body 200 has a diameter 321 which ranges from about 11.736 inches to 11.741 inches (295.91 mm to about 296.16 mm). The ring body 200 includes a lip 225 formed by the inside edge 220 which is utilized to support the substrate thereon. The inside edge 220 of the lip 225 has a height 243 which ranges from about 2.95 mm to about 3.05 mm. In one or more embodiments of the ring body 200, the diameter 321 is about 295.91 mm and the height 343 is about 3.05 mm.

The lip 225 has a second vertical wall 303. The second vertical wall 303 is cylindrical, and has a diameter 322 and a height 342. The height 342 for the second vertical wall 303 is about 0.054 inches (1.37 mm). The diameter 322 ranges from about 11.884 inches to about 11.889 inches (about 301.85 mm to about 301.98 mm). The diameter 321 is smaller than the diameter of the substrate while the diameter 322 is larger than the diameter of the substrate. When a 300 mm substrate deposed on the lip 225, a gap is defined between the substrate and the second vertical wall 303. The gap is less than or equal to about 2.0 mm. In one or more embodiments, the gap between a 300 mm substrate and the second vertical wall 303 is about 0.9 mm.

The ring body 200 has a second lip 306. The second lip is defined between the second vertical wall 303 and the foot 307 of the inclined wall 308. The foot 307 of the inclined wall 308 is a distance 323 from the center of the ring body 200. The difference between distance 323 and the diameter 322 of the second vertical wall 303 defines a length of the second lip 306. In one or more embodiments, the length of the second lip 306 is about 6 mm.

The inclined wall 308 has a top 309 defined at the intersection between the inclined wall 308 and the top 210 of the single ring body 200. The inclined wall 308 is inclined at an angle 360. The inclined angle 360 may be selected to increase the process uniformity over the surface of a substrate. That is, the angle may be adjusted to change the concentration of plasma ions directed towards the center of the substrate. In one or more embodiments, the angle 360 is about 80 degrees. In embodiments wherein the angle 360 of the inclined wall 308 is about zero, the inclined wall 308 may have a vertical rise 341 which is defined as the perpendicular distance between the second lip 306 and the top 201. In one or more embodiments, the vertical rise 341 is about 0.086 inches (about 2.18 mm). This makes a distance from the lip 225 to the top 210 about 0.14 inches (about 3.56 mm).

The body 200 has a top 210. The inner portion of the top 210 intersects the inclined wall 308. The outer portion of the top 210 comes to an intersection 310 with the outside edge 240. The intersection 310 of the top 210 with outside edge 240 may be rounded, chamfered, beveled, angled or have some other type of mating. The angle 360 and type of mating for the intersection 310 provides for a length of the top 210 which may vary. However the outside edge 240 determines the extent for the top 210 length. As shown, the intersection 310 has a radius of about 0.13 inches (about 3.3 mm) between the top 210 and the outside edge 240. Additionally, the outside edge 240 is a cylindrical wall having a diameter 334. The diameter 334 of the outside edge 240 of the ring body 200 is about 15.12 inches (about 384.05 mm).

The outside edge 240 has a top portion which meets the top 210 and a bottom portion which meets the outer bottom 304 of the body 200. The outer bottom 304 is a flat portion of body 200 located between the diameter 333 and the diameter 334. Additionally, a distance between the top 210 and the outer bottom 304 defines a height 350 of the outside edge 240. In one or more embodiments, the outside edge 240 has a height 350 of about 0.475 inches (about 12.07 mm).

The diameter 333 defines the outer portion of the isolator key 305. The diameter 333 of the isolator key 305 configured for use with a 300 mm substrate may be between about 13.785 and about 13.775 inches (about 350.14 mm and about 349.885 mm). The diameter 332 defines the inner portion for the isolator key 305. The diameter 332 of the isolator key 305 configured for use with a 300 mm substrate may be between about 13.045 and about 13.035 inches (about 331.34 mm and about 331.089 mm). The difference between diameter 332 and diameter 333 is the width of the isolator key 305. The isolator key 305 is configured to engage a mating feature of the pedestal such that the single ring body 200 may be precisely positioned on the pedestal. In one or more embodiments, the mating feature of the pedestal disposed in the plasma processing chamber fits into the single ring body 200 at the isolator key 305. The isolator key 305 fits in between the outer bottom 304 and inner bottom 314. The isolator key 305 has a depth 351 from the outer bottom 304 and a depth 352 from the inner bottom 314. The size and configuration for the isolator key 305 is predicated on the size and shape of the isolator in the plasma processing chamber. In one or more embodiments, the isolator key 305 has a depth 351 of about 0.160 inches (about 4.06 mm), a depth 352 of about 0.235 inches (about 5.97 mm) and a width of about 0.74 inches (about 18.80 mm).

The isolator key 305 meets the second bottom 314 at diameter 332. The second bottom 314 extends from diameter 332 inward to vertical surface 315 at diameter 331. The intersection 318 where vertical surface 315 and inner bottom 314 meet may be rounded, chamfered, beveled, angled or possibly some other type of mating. As shown, intersection 318 is rounded and has a radius of about 0.04 inches (1.02 mm). The diameter 331 is configured to fit an electrostatic chuck, and may range from about 12.205 inches to about 12.195 inches (about 310.01 mm to about 309.75 mm). In one or more embodiments, the diameter 331 is about 12.200 inches (about 309.88 mm).

The vertical surface 315 of the center single ring body 200 is defined by a diameter 331. The vertical surface 315 is located between the inner bottom 314 and the lip bottom 316. The height 344 of the vertical surface 315 is the perpendicular distance between the inner bottom 314 and the lip bottom 316. In one or more embodiments, the height 344 of the vertical surface 315 is about 0.292 inches (about 7.42 mm). The vertical surface 315 is positioned adjacent to a portion of the substrate support pedestal.

The lip bottom 316 rests atop the substrate pedestal in the plasma processing chamber. The lip bottom 316 has a width which extends from diameter 331, where lip bottom 316 intersects vertical surface 315, to diameter 321, where lip bottom 316 intersects inside edge 220. The width of lip bottom 316 is the difference between diameter 321 and diameter 331. The width may range between about 0.235 inches and about 0.227 inches (about 5.97 mm and about 5.77 mm). In one or more embodiments, the width of the lip bottom 316 is about 0.232 inches (5.89 mm).

Tooling for the various surfaces may leave a small radius for interior angles. Such radiuses up to a maximum of 0.01 inches (0.25 mm) are generally acceptable, unless otherwise noted. Sharp edges may also be broken by a radius of 0.01 inches (0.25 mm).

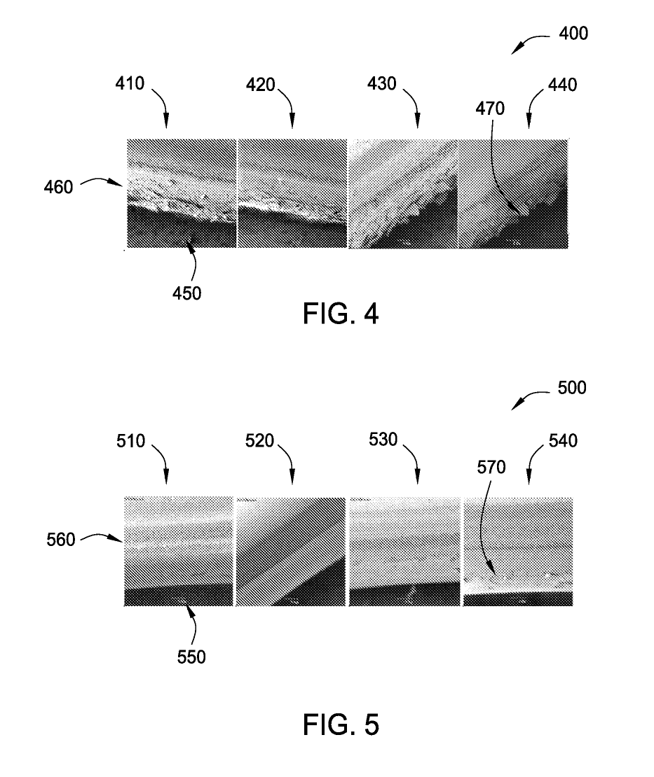

Minimizing the gap between the substrate and the second vertical wall 303 controls the flow of the free radicals around the extreme edge of the substrate. The free radicals influence the amount of defects present at the edge of a substrate. However, the gap provides the necessary clearance for the insertion and removal of the substrate from the cover ring 130 in the plasma processing chamber by a robot. Reducing the gap to less than 1.0 mm has shown significant improvements in the quality of the extreme edge of the substrate. FIG. 4 illustrates edge defects on the wafer extreme edge and backside after etching in an ICP plasma processing chamber with the conventional single ring design. FIG. 4 depicts the extreme edge of a 300 mm substrate after etching with a conventional ring having a gap of about 3.00 mm between the conventional ring and substrate. FIG. 5, conversely, illustrates the extreme edge and backside of the substrate 120 after etching in an ICP plasma processing chamber equipped with the cover ring 130. The substrate 120 shown in FIG. 5 has a 300 mm diameter, and the gap between the cover ring 130 and substrate 120 was about 0.90 mm.

FIG. 4 includes four extreme edge to backside images of a substrate illustrating particle defect arising from bevel polymer peeling after a conventional Al bond pad etch utilizing the conventional wide-gap cover ring. As discussed above, the reduction in particle defects arising from the bond pad etch reduces additional manufacturing steps which would be required to make a substrate acceptable for further processing. The images depict the extreme edge of a 300 mm diameter substrate scanned under an electron microscope. Orienting the substrate with the flat on the bottom, first image 410 depicts the substrate left side extreme edge under such magnification. Bevel polymer peeling 460 is prevalent particularly at the underside 450 of the substrate. Image 420 depicts the flat edge of the substrate (oriented to the bottom) under the same magnification. Image 430 depicts the left side of the edge of the substrate under magnification. Image 440 depicts the top (opposite the flat) of the edge of the substrate under high magnification. Bevel polymer peeling 460 is prevalent on all the edges of the substrate. Therefore, the substrates illustrated in FIG. 4 will require additional operations to clean the bevel edge of the peeling prior to acceptance for additional processing.

FIG. 5, includes four extreme edge to backside images of a substrate after an Al bond pad etch similar to the etch performed on the substrate shown in FIG. 4 except that the etch process utilized the narrow gap cover ring 130 described above. The images of FIG. 5 depict the extreme edge of a substrate having a 300 mm diameter scanned under an electron microscope. The substrate depicted in FIG. 5 was etched using the cover ring 130 having a gap between the substrate and cover ring 130 of about 0.9 mm. Orienting the substrate in a similar fashion as described in FIG. 4 for ease of comparison, the first image 510 depicts the left side of extreme edge of the substrate under magnification. Substantially no bevel polymer peeling 560 is present on the underside 550 of the substrate. Image 520 depicts the flat edge of the substrate (oriented to the bottom) under high magnification. Image 530 depicts the left side of the edge of the substrate under high magnification. Image 540 depicts the top edge of the substrate (opposite the flat) under high magnification. Substantially no bevel polymer peeling 560 is discernible in any of the images. Image 540 has the most visible bevel polymer peeling 570. However, comparing image 540 of FIG. 5 to the corresponding image 440 of FIG. 4, the bevel edge peeling 570 shown in image 540 is improved substantially relative to the bevel edge peeling 470 shown in image 440. The improvement in the bevel edge by reducing the gap the substrate, as illustrated in FIG. 5, is substantial in that the substrate no longer requires additional operations to clean the bevel edge prior to subsequent operations.

The new narrow gap cover ring advantageously extends the process capabilities of the Al bond pad applications to, or beyond, a 3.5 um thick devices. Further, a simple process flow is realized with the new narrow gap cover ring which lowers manufacturing cost by controlling substrate bevel issues without additional tooling, allows installed plasma processing chambers to be cost effectively retrofitted with the inventive cover ring, and allows for the elimination of bevel cleaning after an Al bond pad etch process step. Thus, the new narrow gap cover ring enables “all in one” etching while reducing overall manufacturing costs.

While the foregoing is directed to embodiments of the present invention, other and further embodiments of the invention may be devised without departing from the basic scope thereof, and the scope thereof is determined by the claims that follow:

What is claimed is:

1. A single ring comprising:
a circular ring-shaped body comprising:
an inner surface closest in proximity to a centerline of the body;
an outer surface opposite the inner surface;
a bottom surface with a slot formed therein;
a top surface with an outer end and an inner end, the outer end adjacent to the outer surface, and the inner end adjacent to a slope extending towards the centerline down to a step on the inner surface; and
a lip disposed on the inner surface extending out from a vertical face below the step toward the centerline of the ring, the lip configured to support a substrate thereon, wherein the body is sized to define a gap of less than about 2 mm on the lip between the substrate and the vertical face of the step.

2. The single ring of claim 1, wherein the lip and the inner surface is configured to support a 300 mm diameter substrate.

3. The single ring of claim 2, wherein the gap is about 0.9 mm.

4. The single ring of claim 2, wherein the outer surface has a diameter of about 15.12 inches.

5. The single ring of claim 2, wherein the vertical face forms a cylinder having a diameter of about 11.884 inches to about 11.889 inches.

6. The single ring of claim 1, wherein the lip and the inner surface is configured to support a 200 mm diameter substrate or a 450 mm diameter substrate.

7. The single ring of claim 1, wherein the slope is about 80 degrees.

8. The single ring of claim 1, wherein the slot is a circular grove which divides the bottom surface into an inner bottom surface and an outer bottom surface, and wherein the inner bottom surface and the outer bottom surface are not co-planar.

9. The single ring of claim 2, wherein the height of the vertical wall is about 0.054 inches.

10. The single ring of claim 9, wherein the lip has an inner diameter of about 11.736 inches to about 11.741 inches.

11. The single ring of claim 1, wherein the body is fabricated from a ceramic material.

12. The single ring of claim 11, wherein the ceramic material is Y₂O₃.

13. The single ring of claim 1, wherein a distance from the lip to the top surface is about 0.14 inches.

14. The single ring of claim 1, wherein the body is fabricated from Y₂O₃, the gap is about 0.9 mm, the outer surface has a diameter of about 15.12 inches, the vertical face forms a cylinder having a diameter of about 11.884 inches to about 11.889 inches, the slope is about 80 degrees, the slot is a circular grove which divides the bottom surface into an inner bottom surface and an outer bottom surface, the inner bottom surface and the outer bottom surface are not co-planar, the height of the vertical wall is about 0.054 inches and the lip has an inner diameter of about 11.736 inches to about 11.741 inches, and a distance from the lip to the top surface is about 0.14 inches.
